(19) United States
(12) Patent Application Publication
(10) Pub. No.: US 2016/0336354 A1
(43) Pub. Date: Nov. 17, 2016

(54) DISPLAY PANEL

(71) Applicant: Chunghwa Picture Tubes, LTD., Taoyuan City (TW)

(72) Inventors: Yi-Wen Chiu, Taoyuan City (TW); Yen-Wei Liu, Chiayi County (TW); Ji-Yi Chiou, Taichung City (TW); Ming-Hsiang Lai, Changhua County (TW); Sheng-Fa Liu, Hsinchu County (TW); Ching-Yu Huang, Taipei City (TW); Yi-Fan Niu, Taipei City (TW)

(21) Appl. No.: 14/805,198

(22) Filed: Jul. 21, 2015

(30) Foreign Application Priority Data
May 14, 2015 (TW) 104207420

(51) Int. Cl. H01L 27/12

(52) U.S. Cl. CPC H01L 27/1248

(57) ABSTRACT

A display panel includes an active device array substrate, an opposite substrate, a display medium and a sealant. The active device array substrate includes a substrate, an active device array, a passivation layer and an enhancement layer. A material of the enhancement layer is different from a material of the passivation layer. The opposite substrate is disposed opposite to the active device array substrate. The display medium is disposed between the active device array substrate and the opposite substrate. The sealant is disposed between the active device array substrate and the opposite substrate and surrounds the display medium. An end of the sealant directly contacts the enhancement layer, and a material of the enhancement layer is the same as a material of the sealant.

### CROSS-REFERENCE TO RELATED APPLICATION

This application claims the priority benefit of Taiwan application serial no. 104207420, filed on May 14, 2015. The entirety of the above-mentioned patent application is hereby incorporated by reference herein and made a part of this specification.

### BACKGROUND OF THE INVENTION

1. Field of the Invention

The invention relates to a display apparatus, and more specifically, to a display panel.

2. Description of Related Art

Generally, a display panel includes an active device array substrate, a display medium, and an opposite substrate. The active device array substrate is adhered to the opposite substrate through the adhesive properties of a sealant located at a periphery of the active device array substrate. The display medium is sealed between the active device array substrate and the opposite substrate through the sealant. Usually, the last step of fabricating the active device array substrate is forming a passivation layer made of silicon nitride (SiNx). The sealant of the display panel is mainly made up of silicon oxide (SiOx). Thus, when laser sintering, since the material of silicon nitride and the material of silicon oxide are different, the adhesive strength between the sealant and the active device array substrate will be lowered. Furthermore, the sealant adopts a silicon oxide material, and the silicon oxide material is naturally more brittle than a sealant that adopts ultraviolet glue. Thus, the display panel is more easily cracked when receiving an external force (such as during the cutting process after packaging or during the chip packing process). This lowers the reliability of the structure of the display panel and the fabrication yield.

### SUMMARY OF THE INVENTION

The invention provides a display panel having a better structural reliability and a better processing yield.

The display panel of the invention includes an active device array substrate, an opposite substrate, a display medium, and a sealant. The active device array substrate includes a substrate, an active device array, a passivation layer, and an enhancement layer. The active device array is disposed on the substrate. The passivation layer is disposed on the active device array, and covers the active device array. The enhancement layer is disposed on the passivation layer. A material of the enhancement layer is different from a material of the passivation layer. The opposite substrate is disposed opposite to the active device array substrate. The display medium is disposed between the active device array substrate and the opposite substrate. The sealant is disposed between the active device array substrate and the opposite substrate, and surrounds the display medium. An end of the sealant directly contacts the enhancement layer, and a material of the enhancement layer is the same as a material of the sealant.

In an embodiment of the invention, a material of the enhancement layer is silicon oxide.

In an embodiment of the invention, a thickness of the enhancement layer is between 500 angstroms and 2000 angstroms.

In an embodiment of the invention, the active device array substrate further includes a plurality of active devices and a plurality of pixel electrodes. The active devices are disposed on the substrate. Each pixel electrode is disposed on the enhancement layer, and the pixel electrodes are electrically connected respectively to each active device through one of a plurality of contact openings sequentially penetrating through the enhancement layer and the passivation layer.

In an embodiment of the invention, each active device includes a gate, a gate insulating layer, an active layer, a source, and a drain. The gate is disposed on the substrate. The gate insulating layer is disposed on the substrate and covers the gate. The active layer is disposed on the gate insulating layer. The source and the drain are disposed on two opposite sides of the active layer. A portion of the active layer is exposed between the source and the drain.

In an embodiment of the invention, a material of the active layer includes semiconductor material such as amorphous silicon, polysilicon, metal oxide, or organic material.

In an embodiment of the invention, the active device array substrate further includes a flat layer, disposed between the passivation layer and the source and drain.

In an embodiment of the invention, a thickness of the flat layer in addition with a thickness of the passivation layer is between 1500 angstroms and 3000 angstroms.

In an embodiment of the invention, the active device array substrate further includes a light shielding layer, disposed on the flat layer. An orthogonal projection of the light shielding layer on the substrate covers an orthogonal projection of the active layer on the substrate.

In an embodiment of the invention, the display medium includes a liquid crystal layer, an electrophoresis display film, an organic light emitting layer, or a plurality of quantum particles.

Based on the above, the active device array substrate of the invention includes an enhancement layer. A material of the enhancement layer is the same as a material of the sealant. Thus, the bond strength between the sealant and the active device array substrate is increased. This further improves the structure reliability and processing yield of the display panel of the invention.

### BRIEF DESCRIPTION OF THE DRAWINGS

FIG. 1 is a schematic diagram of a display panel according to an embodiment of the invention.

### DETAILED DESCRIPTION OF DISCLOSED EMBODIMENTS

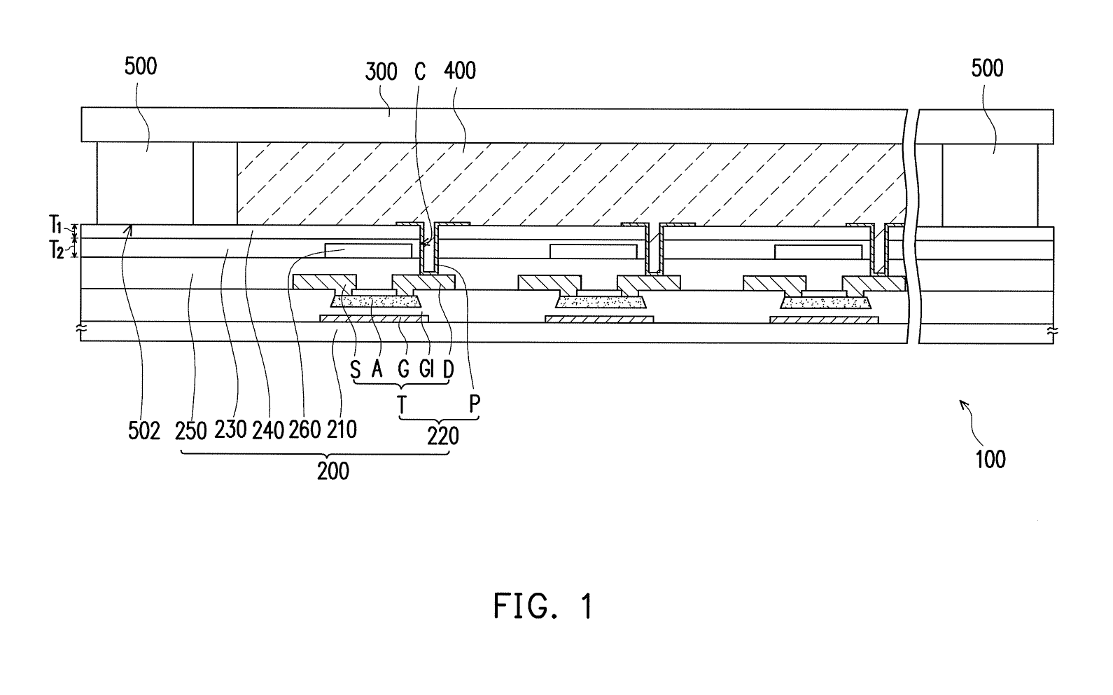

FIG. 1 is a schematic diagram of a display panel according to an embodiment of the invention. Referring to FIG. 1, in the embodiment, the display panel 100 includes an active device array substrate 200, an opposite substrate 300, a display medium 400, and a sealant 500. In detail, the active device array substrate 200 includes a substrate 210, an active device array 220, a passivation layer 230, and an enhancement layer 240. The active device array 220 is disposed on the substrate 210. The passivation layer 230 is disposed on the active device array 220, and covers the active device array 220. The enhancement layer 240 is disposed on the passivation layer 230. A material of the enhancement layer 240 is different from a material of the passivation layer 230. The opposite substrate 300 is disposed opposite to the active device array substrate 200. The display medium 400 is disposed between the active device array substrate 200 and the opposite substrate 300. The sealant 500 is disposed between the active device array substrate 200 and the opposite substrate 300, and surrounds the display medium 400. An end 502 of the sealant 500 directly contacts the enhancement layer 240, and a material of the enhancement layer 240 is the same as a material of the sealant 500.

In particular, in the embodiment, a material of the passivation layer 230 is silicon nitride, and a material of the enhancement layer 240 is silicon oxide. In other words, in the embodiment, a material of the sealant 500 is also silicon oxide. In the embodiment, the materials of the enhancement layer 240 and the sealant 500 are the same, both being for example silicon oxide. Thus, in the embodiment, the bond strength between the sealant 500 and the enhancement layer 240 of the active device array substrate 200 is stronger than that compared with conventional material, where a material of the sealant is, for example, silicon oxide, and a material of the passivation layer is, for example, silicon nitride. In particular, a thickness of the enhancement layer 240 is between 500 angstroms and 2000 angstroms. Preferably, the thickness of the enhancement layer 240 is 500 angstroms. As seen in FIG. 1, a thickness T1 of the enhancement layer 240 is substantially less than a thickness T2 of the passivation layer 230. When fabricating, since the enhancement layer 240 and the passivation layer 230 are disposed in the same location, thus, both layers can use the same mask. Therefore, an additional mask is not required, and the problem of increase in costs for an additional mask during the fabrication process is avoided.

Furthermore, in the embodiment, the active device array substrate 200 further includes a plurality of active devices T and a plurality of pixel electrodes P. The active device T is disposed on the substrate 210. The substrate 210 is, for example, a glass substrate, but the invention is not limited thereto. Each pixel electrode P is disposed on the enhancement layer 240, and each pixel electrode P is electrically connected respectively to each active device T through one of a plurality of contact openings C sequentially penetrating through the enhancement layer 240 and the passivation layer 230. In addition, each active device T includes a gate G, a gate insulating layer GI, an active layer A, a source S, and a drain D. The gate G is disposed on the substrate 210, and the gate insulating layer GI is disposed on the substrate and covers the gate G. The active layer A is disposed on the gate insulating layer GI. The source S and the drain D are disposed on two opposite sides of the active layer A. A portion of the active layer A is exposed between the source S and the drain D. In the embodiment, a material of the active layer A is, for example, semiconductor material such as amorphous silicon, polysilicon (such as low temperature polysilicon), metal oxide (such as indium gallium zinc oxide), or organic material. The invention is not limited thereto.

Furthermore, for better flatness, the active device array substrate 200 of the embodiment can optionally include a flat layer 250, disposed between the passivation layer 230, and the source S and drain D. Herein, the materials of the passivation layer 230 and the flat layer 250 are the same. That is to say, a material of the flat layer 250 of the embodiment is silicon nitride. Furthermore, a thickness of the flat layer 250 in addition with a thickness of the passivation layer 230 is between 1500 angstroms and 3000 angstroms. Preferably, a thickness of the flat layer 250 in addition with a thickness of the passivation layer 230 is 2300 angstroms. In addition, in the embodiment, the active device array substrate 200 can optionally further include a light shielding layer 260, disposed on the flat layer 250. An orthogonal projection of the light shielding layer 260 on the substrate 210 covers an orthogonal projection of the active layer A on the substrate 210. This can effectively reduce interference from external light towards the active device T. Furthermore, in the embodiment, the opposite substrate 300 is, for example, a cover plate or a color filter substrate. The display medium 400 is, for example, a liquid crystal layer, an electrophoresis display film, an organic light emitting layer, or a plurality of quantum particles. The invention is not limited thereto.

In the embodiment, since the materials of the enhancement layer 240 and the sealant 500 are the same, thus, when laser sintering for sealing, the bond strength between the sealant 500 and the enhancement layer 240 is stronger. Furthermore, since the bond strength between the sealant 500 and the enhancement layer 240 is strong, the structure of the display panel 100 is less likely to be cracked when receiving an external force during follow up fabrication processes (such as during the cutting process after packaging or during the chip packing process) . Therefore, in the embodiment, the display panel 100 has better structural reliability and the processing yield.

To sum up, the active device array substrate of the invention includes an enhancement layer. A material of the enhancement layer is the same as a material of the sealant. Thus, the bond strength between the sealant and the active device array substrate is increased. This further improves the structure reliability and processing yield of the display panel of the invention.

1. A display panel, comprising:
an active device array substrate, comprising:
a substrate;
an active device array, disposed on the substrate;
a passivation layer, disposed on the active device array, and covering the active device array; and
an enhancement layer, disposed on the passivation layer, wherein a material of the enhancement layer is different from a material of the passivation layer;
an opposite substrate, disposed opposite to the active device array substrate;
a display medium, disposed between the active device array substrate and the opposite substrate, wherein the display medium contacts a portion of the enhancement layer; and
a sealant, disposed between the active device array substrate and the opposite substrate, and surrounding the display medium, wherein an end of the sealant directly contacts the enhancement layer, and a material of the enhancement layer is the same as a material of the sealant.

2. The display panel as claimed in claim 1, wherein a material of the enhancement layer is silicon oxide.

3. The display panel as claimed in claim 1, wherein a thickness of the enhancement layer is between 500 angstroms and 2000 angstroms.

4. The display panel as claimed in claim 1, wherein a material of the passivation layer is silicon nitride and the passivation layer contacts the enhancement layer.

5. The display panel of claim 1, wherein the active device array substrate further includes:
a plurality of active devices, disposed on the substrate; and
a plurality of pixel electrodes, disposed on the passivation layer, wherein the passivation layer and the enhancement layer are located between the active devices and the pixel electrodes, the pixel electrodes are extended into one of a plurality of contact openings to be electrically connected respectively to the corresponding active devices, wherein each of the contact openings passes through the passivation layer and the enhancement layer.

6. The display panel as claimed in claim 5, wherein each of the active devices comprise:
a gate, disposed on the substrate;
a gate insulating layer, disposed on the substrate and covering the gate;
an active layer, disposed on the gate insulating layer; and
a source and a drain, disposed on two opposite sides of the active layer, wherein a portion of the active layer is exposed between the source and the drain.

7. The display panel as claimed in claim 6, wherein a material of the active layer comprises amorphous silicon, polysilicon, metal oxide, or organic material.

8. The display panel as claimed in claim 6, wherein the active device array substrate further includes:
a flat layer, disposed between the passivation layer, and the drain and the source.

9. The display panel as claimed in claim 8, wherein a material of the passivation layer is the same as a material of the flat layer.

10. The display panel as claimed in claim 9, wherein the material of the flat layer is silicon nitride.

11. The display panel as claimed in claim 8, wherein a thickness of the flat layer in addition with a thickness of the passivation layer is between 1500 angstroms and 3000 angstroms.

12. The display panel as claimed in claim 8, wherein the active device array substrate further includes:
a light shielding layer, disposed on the flat layer, and an orthogonal projection of the light shielding layer on the substrate covers an orthogonal projection of the active layer on the substrate.

13. The display panel as claimed in claim 1, wherein the display medium includes a liquid crystal layer, an electrophoresis display film, an organic light emitting layer, or a plurality of quantum particles.

14. The display panel as claimed in claim 1, wherein a thickness of the enhancement layer is less than a thickness of the passivation layer.

15. The display panel as claimed in claim 1, wherein the opposite substrate includes a cover plate or a color filter substrate.
